(19) United States
(12) Patent Application Publication
(10) Pub. No.: US 2003/0005385 A1
(43) Pub. Date: Jan. 2, 2003

(54) Optical communication system with variable error correction coding

(76) Inventor: Ronald D. Stieger, Kirkland, WA (US)

Correspondence Address: Lawrence E. Lycke, BLAKELY, SOKOLOFF, TAYLOR & ZAFMAN LLP, Seventh Floor, 12400 Wilshire Boulevard, Los Angeles, CA, 90025-1026, US

(21) Appl. No.: 09/894,189

(22) Filed: Jun. 27, 2001

(51) Int. Cl. G06F 11/00; H03M 13/00; H04B 10/08

(52) U.S. Cl. 714/758; 714/704; 714/752; 359/110

(57) ABSTRACT

A free space optical communication system with variable error correction includes an optical transmitter having a variable error correction encoder and an optical receiver having variable error correction decoder. The optical transmitter can encode the data to be transmitted with an error correction code having a data rate that varies depending on to the error rate or predicted error rate of the optical signal to optimize throughput of the data while maintaining accuracy.

### TECHNICAL FIELD

This disclosure relates generally to communication systems, and in particular but not exclusively, relates to wireless optical communication systems.

### BACKGROUND

With the increasing popularity of wide area networks (e.g., the Internet and/or World Wide Web), network growth and traffic have exploded in recent years. Network users continue to demand faster networks, and as network demands continue to increase, existing network infrastructures and technologies are reaching their limits.

Wireless optical telecommunications technology is one alternative to existing hardwire or fiber network solutions. Wireless optical telecommunications use light beams, such as lasers, as optical communications signals. In typical wireless optical communication systems, an optical transmitter transmits data (encoded into a beam of light) through free space to an optical receiver.

However, the free space environment can variably attenuate the optical beams. For example, rain, fog, snow and weather conditions may significantly attenuate the optical beams used in optical communication systems, while essentially no attenuation occurs in clear weather. Designing a system that is efficient and accurate under variable attenuation conditions can be difficult.

### SUMMARY

In accordance with aspects of the present invention, a free space optical communication system with variable error correction is provided. In one aspect, the free space optical communication system includes an optical transmitter having a variable error correction encoder and an optical receiver having variable error correction decoder. In operation, the optical transmitter can encode the data to be transmitted with an error correction code having a data transfer rate that varies depending on to the error rate (or predicted error rate) of the optical signal. The term “data transfer rate” is used in this context to refer to the ratio of data bit rate (as opposed to error correction bits) to the total bit rate. For example, for a relatively low error rate (or predicted error rate), the optical transmitter would transmit the data with no error correction coding. For a slightly higher error rate (or predicted error rate), the optical transmitter would encode the data with an error correction code having a relatively high data transfer rate. For a relatively high error rate (or predicted error rate), the optical transmitter would encode the data with an error correction code having a relatively low data transfer rate. This aspect advantageously allows the free space optical communication system to select, if needed, an error correction code that optimizes throughput while maintaining accuracy.

In another aspect of the invention, the optical receiver includes an error rate indicator. In one embodiment, the error rate indicator predicts the error rate by measuring the power of the received optical signal. The error rate generally increases with decreased power of the received optical signal. The optical receiver would then provide an indication of the power level to the optical transmitter, which would then encode the data (if needed) using an error correction code with the appropriate data rate.

In yet another aspect of the invention, the free space optical communication system includes an optical transceiver. The optical transceiver can determine or predict the error rate for received optical signals and provide error correction coding for optical signals to be transmitted based on that error rate. This aspect advantageously allows the optical transceiver to determine itself whether to use an error correction code with no input from the optical receiver (or the target optical transceiver).

In still another aspect of the invention, transmitted optical signal includes a separate modulation to indicate the error correction coding, if any, being used to encode the data. In one embodiment, a tone modulation technique is used. This aspect can help simplify how an optical receiver or transceiver determines whether a received optical signal is error correction coded.

### BRIEF DESCRIPTION OF THE DRAWINGS

Non-limiting and non-exhaustive embodiments of the present invention are described with reference to the following figures, wherein like reference numerals refer to like parts throughout the various views unless otherwise specified.

FIG. 1 is a block diagram illustrating a free space optical communication system, according to one embodiment of the present invention.

FIG. 2 is a flow diagram illustrating an operation of the free space optical communication system depicted in FIG. 1, according to one embodiment of the present invention.

FIG. 3 is a block diagram illustrating a transceiver for use in a free space optical communication system, according to one embodiment of the present invention.

FIG. 4 is a flow diagram illustrating an operation of the transceiver depicted in FIG. 3, according to one embodiment of the present invention.

FIG. 5 is a block diagram illustrating a variable error correction encoder, according to one embodiment of the present invention.

FIG. 6 is a block diagram illustrating a variable error correction decoder, according to one embodiment of the present invention.

FIG. 7 is a block diagram illustrating a variable error correction encoder/decoder implementation, according to one embodiment of the present invention.

### DETAILED DESCRIPTION OF THE ILLUSTRATED EMBODIMENTS

Embodiments of a system and method for a free space optical communication system with variable error correction are described herein. In the following description, numerous specific details are set forth to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

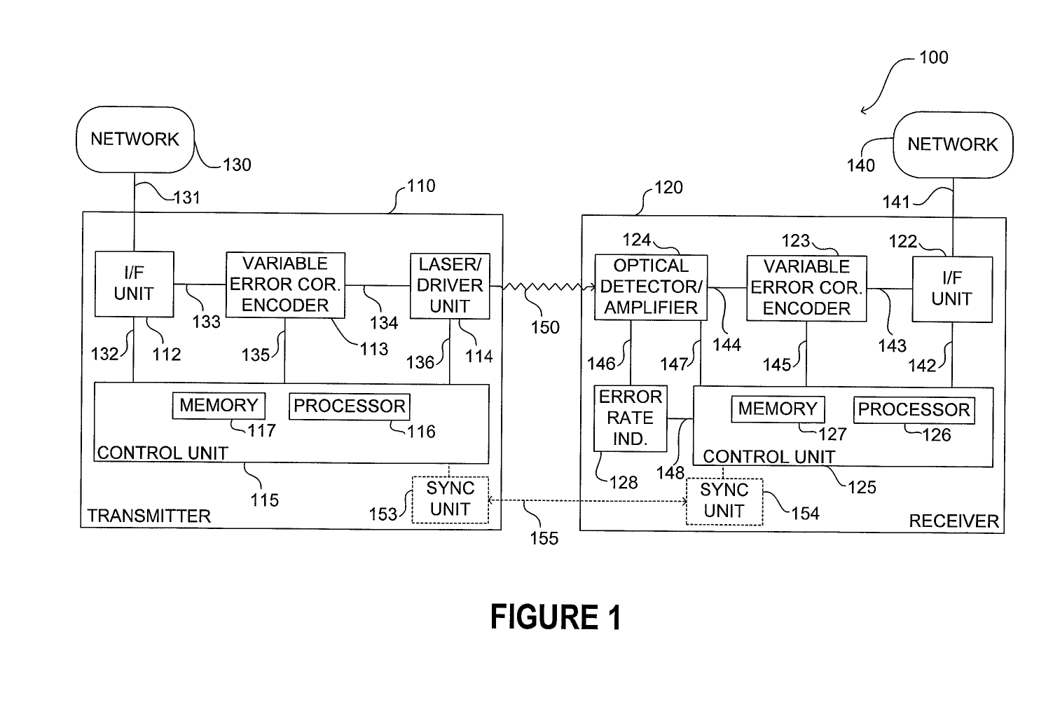

FIG. 1 illustrates a free space optical communication system 100, according to one embodiment of the present invention. In this embodiment, free space optical communication system 100 includes an optical transmitter 110 having an interface unit 112, a variable error correction encoder 113, a laser/driver unit 114, and a control unit 115. This embodiment of control unit 115 includes a processor 116 and a memory 117.

Free space optical communication system 100 also includes an optical receiver 120 having an interface unit 122, a variable error correction decoder 123, an optical detector/amplifier unit 124, and a control unit 125. This embodiment of control unit 125 includes a processor 126 and a memory 127. In addition, optical receiver 120 includes an error rate indicator 128. Error rate indicator 128 outputs a signal that provides an indication of a parameter of a received optical signal related to error rate. In one embodiment, error rate indicator 128 measures the power level of a received optical signal.

The elements of optical transmitter 110 are interconnected as follows. Interface unit 112 is connected to a network 130 via a line 131. The term “line” as used in this context can also refer to a bus, optic fiber, coaxial cable, other single or multiple conductor electrical connection. Network 130 can be any type of interconnected network operated by a carrier such as, for example, a Public Switched Telephone Network (PSTN), a Local Carrier Exchange (LEC) network, an Interexchange Carrier (IXC), a satellite network, or other public or private networks. Network 130 may also be a collection of networks such as the Internet, or a data communication network such as a Local Area Network (LAN), Metropolitan Area Network (MAN) or Wide Area Network (WAN). In addition, interface unit 112 is connected to control unit 115 and variable error correction encoder 113 via lines 132 and 133, respectively. Variable error correction encoder 113 is also connected to laser/driver unit 114 and control unit 115 via lines 134 and 135, respectively. Laser/driver circuit 114 is also connected to control unit 115 via a line 136.

The elements of optical receiver 120 are interconnected as follows. Interface unit 122 is connected to a network 140 (as defined for network 130), control unit 125, and variable error correction decoder 123 via line 141,142 and 143, respectively. Variable error correction decoder 123 is connected to optical detector/amplifier 124 and to control unit 125 via lines 144 and 145, respectively. Optical detector/amplifier 124 is connected to error rate indicator 128 and to control unit 125 via lines 146 and 147, respectively. Error rate indicator 128 is connected to control unit 125 via a line 148.

In accordance with the present invention, variable error correction encoder 113 can execute various error correction encoding algorithms that provide various data transfer rates (which tend to be inversely related to the error correction performance). For example, in one embodiment, variable error correction encoder 113 may selectively encode the data using one error correction algorithm under one a set of conditions and provide no error correction encoding under another set of conditions. Thus, this embodiment of variable error correction encoder 113 may advantageously provide no error correction coding to maximize the data transfer rate when the error rate of the optical communication signaling is relatively low. However, if the error rate is relatively high, this embodiment of error correction encoder 113 can then switch to provide error correction coding so that errors can be corrected. Under such conditions, the lower data transfer rate resulting from the error correction coding may be better than the effective data transfer rate that results from having to retransmit data (when an error occurs) if no error correction coding is used (i.e., resulting in improved latency).

In other embodiments, variable error correction encoder 113 may selectively provide no error correction encoding, or encode the data using an error correction algorithm selected from two or more error correction algorithms. In one embodiment, these error correction algorithms have a different combination of error correction performance and data transfer rate. Many such forward error correction algorithms are known. For example, in various embodiments the error correction algorithms can include one or more forward error correction algorithms such as, for example, block codes, Reed Solomon codes, cyclic codes, and convolutional codes. In addition, each of these forward error correction codes have variable metrics or parameters such as, for example the n and k values of block codes, which affect the data transfer rate and error correction performance. Thus, for example, error correction encoder 113 can be configured with two error correction algorithms. The first could be an error correction code having a relatively high data transfer rate and low error correction performance for low error rate conditions. The second could be an error correction algorithm having a relatively low data transfer rate and high error correction performance for high error rate conditions. For example, in one embodiment, the first error correction algorithm could be a (255, 241) Reed Solomon code, and the second could be a (255, 55) Reed Solomon code.

In light of the present disclosure, those skilled in the art will recognize that error correction encoder 113 could be configured with any number of error correction algorithms having different combinations of data transfer rates and error correction performance to optimize the effective data transfer rate for various error rate conditions.

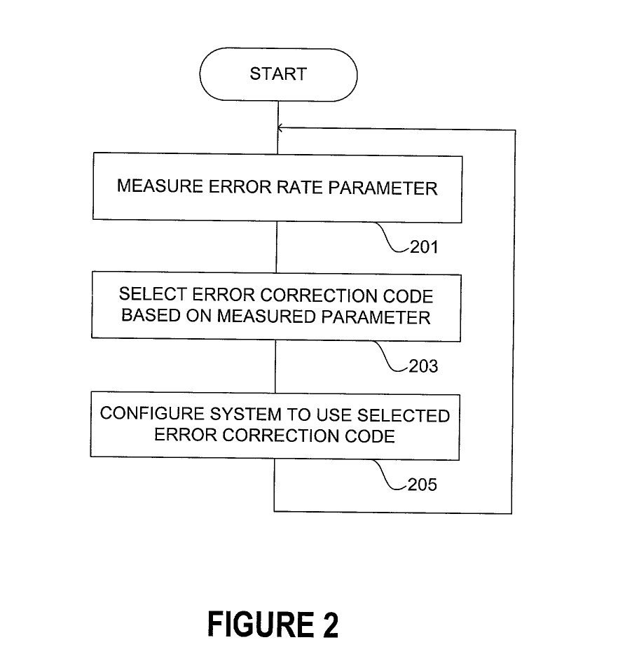

This embodiment of free space optical communication system 100 operates generally as follows. Network 130 can send data to network 140 via free space optical communication system 100. For example, network 130 can provide data to optical transmitter 110 via line 131, conforming to the protocol used by the network. Interface unit 112 can be substantially similar to corresponding interface units used in conventional optical communication systems. Thus, interface unit 112, configured with the protocol, extracts the data for transmission by optical transmitter 110. However, in accordance with the present invention, this data may be error correction coded by variable error correction encoder 113 before transmission to optical receiver 120. This feature is described below in more detail in conjunction with FIG. 2.

Laser/driver unit 114 receives data (which need not be error correction encoded) from variable error correction encoder 113 and transmits a modulated laser beam, indicated by an arrow 150, to optical receiver 120. As in a conventional system, optical detector/amplifier 124 receives and demodulates the received optical signal. In particular, in one embodiment, optical detector/amplifier 124 converts the optical signal into an analog electrical signal with a voltage (or current) that is related to the intensity of the optical signal. For example, optical detector/amplifier 124 can generate an electrical signal having a voltage that is proportional to the power of the optical signal. Optical detector/amplifier 124 also determines the bits (which include the data and the error correction bits) from these samples. For example, in a system that uses on-off keying (OOK) to modulate bits on the optical signal, optical detector/amplifier 124 can also regenerate the transmitted bits from the electrical signal with the proper timing and shape.

Variable error correction decoder 123 receives the bits from optical detector/amplifier 124. Variable error correction decoder 123 decodes (from the error correction encoding, if any, provided by variable error correction encoder 113) the received bits to extract the actual data. Variable error correction decoder 123 provides the extracted data to interface unit 122, which then provides the data to network 140, conforming with the protocol used by network 140.

Turning now to FIGS. 1 and 2, free space optical communication system 100 operates as follows in selecting an error correction code. In a step 201, free space optical communication system 100 measures a parameter related to the error rate of the received optical signal. This parameter can be the error rate itself, or an indirect indicator of the error rate. For example, in one embodiment, error rate indicator 128 is used to measure the power of the received optical signal. The power of the received optical signal can depend on conditions in the free space optical path between optical transmitter 110 and optical receiver 120. For example, precipitation, fog, smog, smoke, etc. may attenuate the optical signal. This attenuation would reduce the signal-to-noise ratio of the received optical signal, which would tend to increase the error rate. Thus, measuring the power level of the received optical signal provides an indirect indication or a prediction of the error rate of the received optical signal. In another embodiment, variable error correction decoder 123 may be implemented to detect and track errors while performing the error correction decoding operation to provide a direct measurement of the error rate.

In a step 203, free space optical communication system 100 selects an error correction code based on the measurement of step 201. In one embodiment, control unit 125 receives the measurement from error rate indicator 128 and compares the measurement with a predetermined mapping of measurement ranges to error correction codes. For example, control unit 125 may be configured to map the measurements to error correction codes as follows. Measurements below a predetermined value N are mapped to no error correction coding. Measurements between N and N+X are mapped to a high data transfer rate code. Measurements between N+X and N+X+Y are mapped to moderate data transfer rate code; and measurements greater than N+X+Y are mapped to a low data transfer rate code. In other embodiments, control unit 125 could be configured with different mappings (e.g., different number and sizes of measurement ranges). In still other embodiments, control unit 115 of optical transmitter 110 may be configured with the mapping.

In a step 205, free space optical communication system 100 configures variable error correction encoder 113 and variable error correction decoder 123 to use the error correction code selected in step 203. In one embodiment, optical transmitter 110 and optical receiver 120 may include optional synchronization units 153 and 154, respectively. In these embodiments, synchronization units 153 and 154 are used to synchronize error correction encoder 113 with error correction decoder 123 so that optical receiver 120 can properly recover the data from the received optical signal. Synchronization units may be a wired link, such as a telephone connection or a DSL (digital subscriber line) connection, or a wireless link such as an RF (radio frequency) link. In one embodiment, control unit 125 (of optical receiver 120) sends a message to control unit 115 (of optical transceiver 110) via synchronization units 153 and 154 with the error correction code selected in step 203. Error correction encoder 113 can then begin encoding the data before transmission by laser/driver unit 114.

In another embodiment, control unit 125 provides the measurement from error rate indicator 128 to control unit 115 via synchronization units 153 and 154 so that control unit 115 can select the error correction code. Control unit 115 would then send a return message to control unit 125 via synchronization units 154 and 153 with the selected error correction code.

Alternatively, in embodiments in which one error correction code is used, control unit 125 can send a message indicating that the error correction encoding should be activated (or de-activated), with control unit 115 responding with a signal indicating optical transmitter 110 is currently transmitting or will begin transmitting the optical signal with (or without) error correction coding.

In yet embodiment, the encoding can include a synchronization symbol (e.g. a unique bit pattern) that indicates the associated transmitted data is error correction encoded with a particular algorithm. Optical receiver 120 would be configured to recognize the synchronization symbol and cause variable error correction decoder 123 to select the decoding algorithm corresponding to the error correction code indicated by the synchronization symbol.

In still another embodiment, the encoding can also include additional modulation of the transmitted optical signal with a synchronization signal that indicates that the associated data contained in the optical signal is encoded with a particular error correction code. For example, the optical signal may be tone modulated, as described in “Laser Communications in Space”, Lambert and Casey, Artech House, 1995, pages 63-64. Optical receiver 120 would be configured to recognize the synchronization signal and cause variable error correction decoder 123 to select the decoding algorithm corresponding to the error correction code indicated by the synchronization signal.

The operational flow then returns to step 201 to monitor the error rate parameter again. In this way, when the error rate conditions change, free space optical communication system 100 can adapt to the new conditions by terminating or changing the error correction code to provide an optimal data transfer rate.

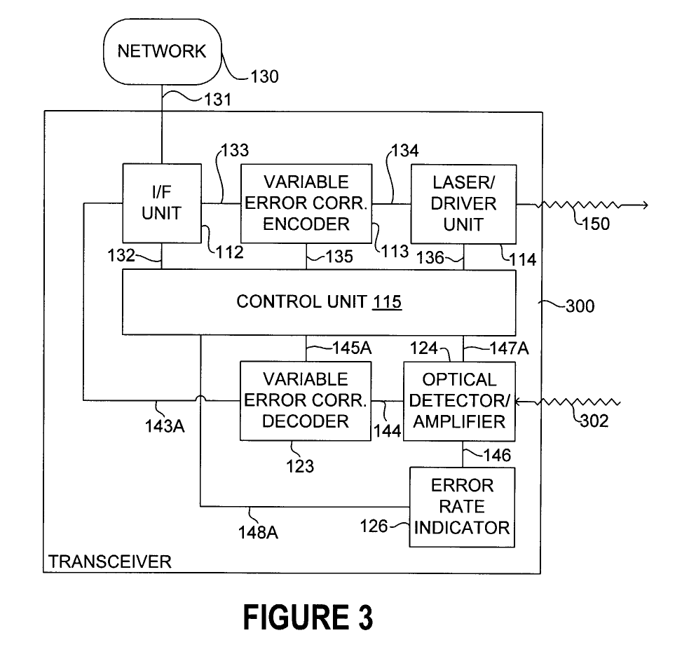

FIG. 3 illustrates an optical transceiver 300 with variable error correction encoding/decoding for use in a free space optical communication system 100, according to one embodiment of the present invention. In this embodiment, optical transceiver 300 combines elements from optical transmitter 110 (FIG. 1) and optical receiver 120 (FIG. 1) to form a unit that can both transmit and receive optical signals. In particular, optical transceiver 300 includes interface unit 112, variable error correction encoder 113, laser/driver unit 114, control unit 115, variable error correction decoder 123, optical detector/amplifier 124 and error rate indicator 126.

These elements are interconnected as described above in conjunction with FIG. 1, except that variable error correction decoder 123, optical detector/amplifier 124 and error rate indicator are connected to control unit 115 (via lines 145A, 147A and 148A) instead of control unit 125 (FIG. 1). In addition, variable error correction decoder 123 is connected to interface unit 112 (via line 143A) instead of to interface unit 122 (FIG. 1).

Optical transceiver 300 operates in substantially the same manner as described above for optical transmitter 110 (FIG. 1) in transmitting an optical signal. Similarly, optical transceiver 300 operates in substantially the same manner as described above for optical receiver 120 (FIG. 1) in receiving an optical signal.

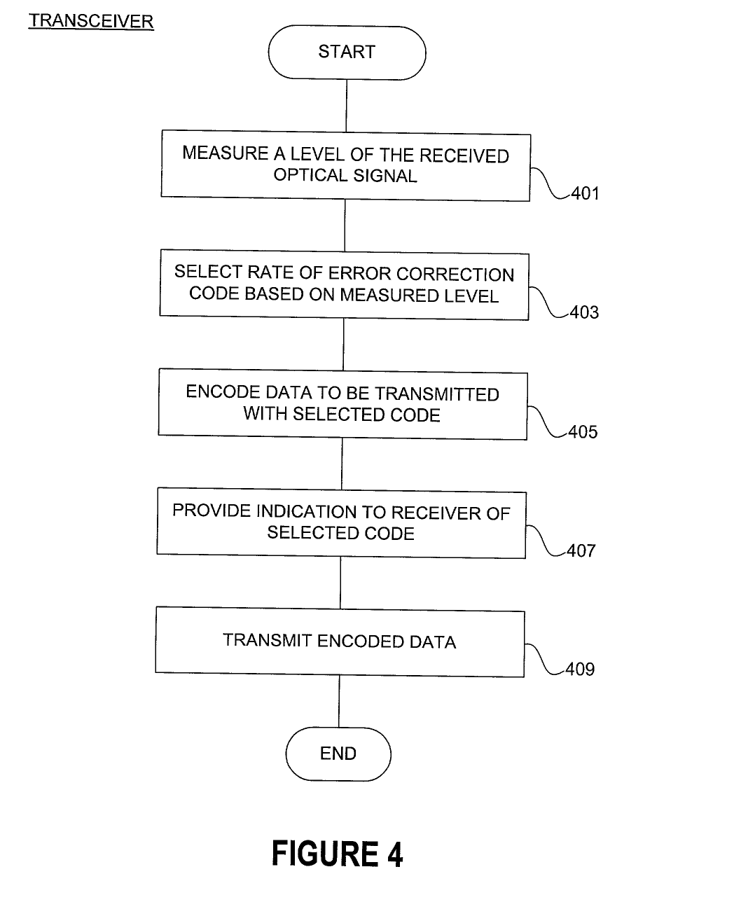

In addition, one embodiment of optical transceiver 300 can be implemented to simplify the process of measuring the error rate conditions and selecting the error correction code to be used. This process is illustrated in the flow chart of FIG. 4.

Referring to FIGS. 3 and 4, optical transceiver 300 operates as follows in selecting an error correction code, according to one embodiment of the present invention. In a step 401, optical transceiver 300 measures the power level (or energy level) of a received optical signal, indicated by an arrow 302. In one embodiment, optical detector/amplifier 124 receives the optical signal. Error rate indicator 126 then determines the power or energy of received optical signal. For example, one implementation of optical detector/amplifier 124 converts the optical energy of the received optical signal into an electrical signal having a voltage proportional to the energy of the received optical signal. In other embodiments, a different parameter of the electrical signal may used, where this parameter has a known relationship to the energy or power of received optical signals. Error rate indicator 126 can measure or determine the average current dissipated by optical detector/amplifier 124 to provide an indication of the power or energy of the received optical signal.

Even though this error rate indication is related to the received optical signal, for some embodiments this system is advantageous. For example, for optical communication between transceiver 300 and another optical transceiver, the error rate indication from step 401 is likely to be similar for both received and transmitted optical signals between optical transceiver 300 and the other optical transceiver. More specifically, the optical path is likely to be the same for both transmitted and received optical signals, thereby causing the same attenuation of optical signals transmitted between optical transceiver 300 and the other optical transceiver. Thus, the error rate indication of step 401 is likely to be the applicable to the optical signals that optical transceiver 300 transmits to the other optical transceiver.

In a step 403, optical transceiver 300 selects an error correction code based on the measured power or energy level. In one embodiment, control unit 115 receives the measurement from error rate indicator 126 and then determines the appropriate error correction code for the measurement (e.g., by look-up table). That is, as previously described, variable error correction encoder 113 is configured with one or more error correction codes having varying data transfer rates and error correction performance. Control unit 115 can then configure variable error correction encoder 113 with the selected error correction code that provides an optimal combination of data transfer rate and error correction performance in view of the expected error rate.

In a step 405, the data to be transmitted is encoded with the error correction code selected in step 403. In one embodiment, after being configured by control unit 115 to use the selected error correction code, variable error correction encoder 113 encodes the data to be transmitted.

In a step 407, the selected error correction code (i.e., information indicating which error correction code optical transceiver 300 is using) is provided to the intended target optical receiver or transceiver so that the intended target can decode the encoded data. In one embodiment, optical transceiver 300 informs the intended target optical receiver or transceiver that data in an incoming optical signal is (or will be) encoded with a particular error correction code. For example, optical transceiver 300 can include a synchronization unit as described above in conjunction with FIG. 1. Alternatively, optical transceiver 300 may add a predetermined synchronization symbol or bit pattern defining the error correction code used on data associated with the symbol or pattern, as previously mentioned. In another alternative, the transmitted optical signal can include a secondary modulation (e.g., tone modulation) that indicates which error correction coding is being used, also described above in conjunction with FIG. 1.

In a step 409, the encoded signal is transmitted as part of an optical signal. In this embodiment, variable error correction encoder 113 provides the encoded data to laser/driver unit 114, which then modulates the data onto an optical signal, such as a laser beam having a wavelength of about 1550 nm (in other embodiments or applications, the wavelength can be any wavelength in the visible, infrared, or ultraviolet spectrum.

In an alternative embodiment, transceiver 300 can measure the power or energy level of received optical signals and select an optimal error correction code as described above in conjunction with steps 401 and 403 above. However, instead of performing steps 405, 407 and 409, in this alternative embodiment, information indicating the selected error correction code is sent to the optical transceiver that sent the received optical signal, which would then perform the equivalent of steps 405, 407 and 409. For example, this information can sent via tone modulation techniques or in a separate configuration or control segment that can be detected and processed by the optical transceiver that sent the received optical signal.

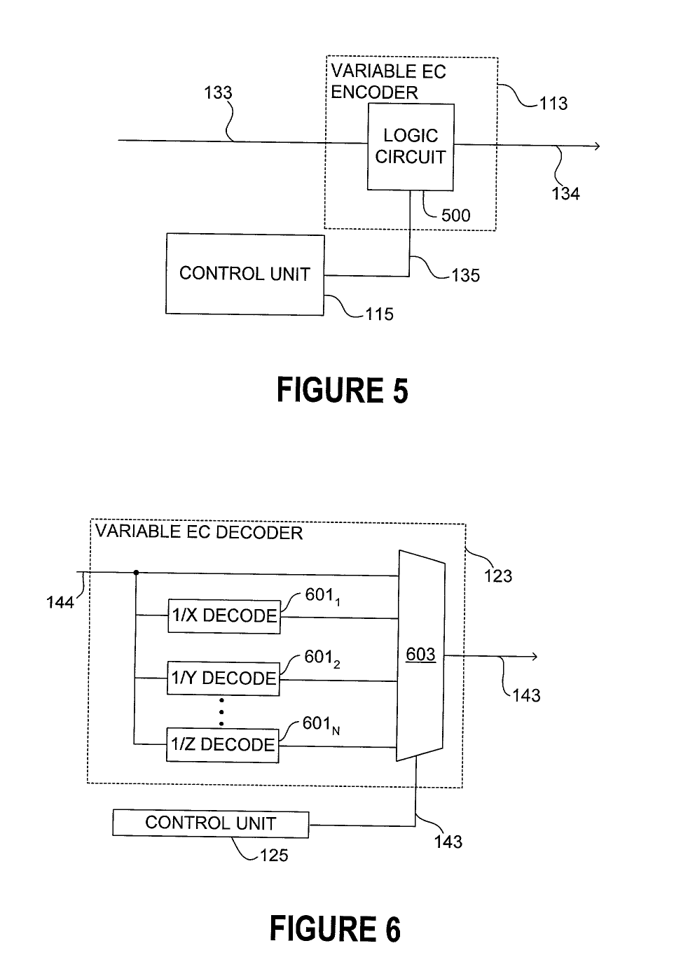

FIG. 5 illustrates an implementation of variable error correction encoder 113, according to one embodiment of the present invention. In this embodiment, variable error correction encoder 113 includes a logic circuit 500 that performs the error correction algorithms. In view of the present disclosure, those skilled in the art will be able to design a suitable logic circuit to implement the predetermined error correction codes without undue experimentation. For example, logic circuit 500 can be implemented using a programmable logic circuit or an ASIC (application specific integrated circuit) designed to perform the predetermined error correction code encoding on data received via line 133, in response to a control signal provided by control unit 115 via line 135. In one embodiment, this control signal can be a multi-bit signal. Such error correction encoding circuit designs are commercially available (e.g., an error correction encoder “core” can be licensed from several vendors). Further, in embodiments using a programmable logic device, error correction encoder designs are available from the vendor of the programmable logic device or other vendors.

FIG. 6 illustrates an implementation of variable error correction decoder 123, according to one embodiment of the present invention. In this embodiment, variable error correction decoder 123 includes decode circuits 601₁, 601₂, . . . , 601_{N} (N being an integer greater than two) and a multiplexer 603. Decode circuits 601₁, 601₂, . . . , 601_{N} are error correction decoders for the different error correction codes that can be selected by variable error correction encoder 113 (FIG. 1). As previously described, variable error correction encoder 113 can use any number of error correction codes greater than one, so in these cases the number of decode circuits in variable error correction decoder 123 would match the number of possible error correction codes that can be used to encode the data.

Decode circuit 601₁, 601₂, . . . , 601_{N} provide different data transfer rates of 1/X, 1/Y, . . . , 1/Z, respectively (X, Y, . . . , Z each being an integer greater than one). For example with N being four, decode circuits 601₁, 601₂, 601₃, and 601₄ can respectively decode error correction codes having data transfer rates of 95%, 75%, 25% and 10% of the transmission bit rate.

The elements of this embodiment of variable error correction decoder 123 are interconnected as follows. Decoder circuits 601₁, 601₂, . . . , 601_{N} each have an input lead connected to line 144 to receive data from optical detector/amplifier 124 (e.g., FIG. 1). Line 144 and the output leads of decode circuits 601₁, 601₂, . . . , 601_{N} are connected to input terminals of multiplexer 603. The control and output leads of multiplexer 603 are respectively connected to control unit 125 via line 143 and to interface unit 122 (e.g., FIG. 1) via line 143.

In operation, decode circuits 601₁, 601₂, . . . , 601_{N} all operate on the data provided on line 144 concurrently. Of course, only the output data of the decode circuit corresponding to the error correction code being used by variable error correction encoder 113 (e.g., FIG. 1) will be accurate. In this embodiment, control unit 125 knows the selected error correction code (e.g., step 407 described above in conjunction with FIG. 4) and generates the control signal to multiplexer 603 (via line 143) to select the corresponding decode circuit (or the data directly from line 144 when no error correction encoding is used). In other embodiments, optical detector/amplifier 124 (FIG. 1) may provide the control signal to multiplexer 603. This alternative embodiment may be advantageously used when the received optical signal contains a symbol or bit pattern that indicates the selected error correction code.

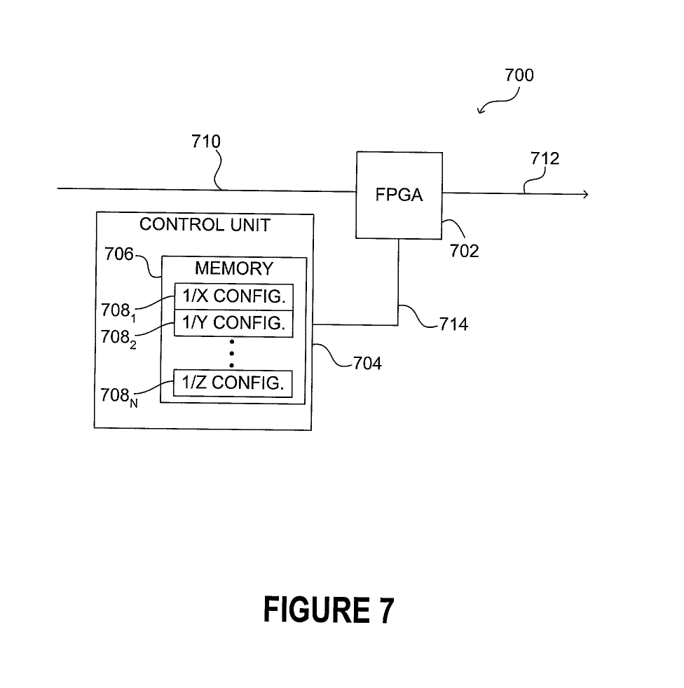

FIG. 7 illustrates a circuit 700 that can be used as either a variable error correction encoder or a variable error correction decoder in free space optical communication system 100 (FIG. 1). In one embodiment, circuit 700 includes a field programmable gate array 702 and a control unit 704. Control unit 704, in this embodiment, includes a memory 706 storing configuration information for the error correction codes used in free space optical communication system 100 (FIG. 1). The information associated with each error correction code is represented in FIG. 7 by blocks 708₁, 708₂, . . . , 708_{N}. This information can include the error correction encoding configuration(s) to implement variable error correction encoder 113 (FIG. 1), or the error correction decoding configuration(s) to implement variable error correction decoder 123 (FIG. 1).

In this embodiment, FPGA 702 is connected to receive data via a line 710. For example, this data can be from interface unit 112 when circuit 700 is used to implement variable error correction encoder 113, or from optical detector/amplifier 124 when circuit 700 is used to implement variable error correction decoder 123. FPGA 702 provides the processed data onto a line 712 (which can serve as line 134 or line 143, depending on whether circuit 700 is used to implement a variable error correction encoder or decoder). Control unit 704 is connected, via a line 714, to a port of FPGA 702 used in programming FPGA 702. Thus, for example, FPGA 702 can be programmed to provide the same functionality as logic circuit 500 (FIG. 5) to implement variable error correction encoder 113. In another example, FPGA 702 can be implemented to provide the same functionality as decode circuits 601₁, 601₂, . . . , 601_{N} and multiplexer 603 (FIG. 6) to implement variable error correction decoder 123 (FIG. 1).

In some embodiments, FPGA 702 is not reprogrammable. PGA 702 would then be programmed with all of the preselected error correction codes prior to installation in optical transmitter 110 (FIG. 1), optical receiver 120 (FIG. 1) or optical transceiver 300 (FIG. 3). Control unit 702 can then be omitted. Such an embodiment could resemble the encoder of FIG. 6.

In alternative embodiments, FPGA 702 can be implemented with a non-volatile reprogrammable FPGA that is programmed as described above for the non-reprogrammable embodiment. Control unit 704 may be included so that FPGA 702 can be upgraded, for example, with different error correction code configurations. In this embodiment (and other embodiments in which FPGA 702 can be reprogrammed), control unit 704 may be implemented using either control unit 115 or 125 (see FIG. 1), depending on whether circuit 700 is used as a variable error correction encoder or decoder.

In other alternative embodiments, FPGA 702 can be implemented with an SRAM-based FPGA that can be dynamically reprogrammed to perform the selected error correction code as needed. These embodiments can advantageously allow the use of a smaller, less expensive FPGA compared to an embodiment that programs FPGA 702 with all of the preselected error correction code configurations. Of course, an SRAM-based FPGA can also be programmed with all of the preselected error correction code configurations. For example, such an embodiment can also be used to implement the encoder of FIG. 6 so that the error correction decoding algorithms can be easily upgraded via control unit 125. (which can serve as control unit 704) without the need for special programming voltages.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various equivalent modifications are possible within the scope of the invention, as those skilled in the relevant art will recognize.

These modifications can be made to the invention in light of the above detailed description. The terms used in the following claims should not be construed to limit the invention to the specific embodiments disclosed in the specification and the claims. Rather, the scope of the invention is to be determined entirely by the following claims, which are to be construed in accordance with established doctrines of claim interpretation.

What is claimed is:

1. An optical communication system, comprising:
an optical transmitter comprising:
an error correction encoder, wherein the error correction encoder to output data that is encoded according to an error correction code selected from a predetermined set of error correction codes having differing data transfer rates, and
a laser/driver unit coupled to the error correction encoder, wherein the laser/driver unit to transmit optical signals modulated with data from the error correction encoder; and
an optical receiver comprising:
an optical detector/amplifier to receive optical signals, and
An error correction decoder coupled to the optical detector/amplifier, wherein the error correction decoder to decode data according to the error correction code selected in the error correction encoder.

2. The system of claim 1, wherein the optical receiver further includes an error rate indicator, wherein the error rate indicator to provide an indication of an error rate of an optical signal received by the optical receiver.

3. The system of claim 2, wherein the error rate indicator is coupled to the optical detector/amplifier.

4. The system of claim 2, wherein the error rate indicator to provide an indication of a power level of the optical signal received by the optical receiver.

5. The system of claim 2, wherein the optical receiver to further provide information related to the error rate indication from the error rate indicator to the optical transmitter.

6. The system of claim 5, wherein the error correction encoder to further select an error correction code of the predetermined set of error correction codes in dependence on the information related to the error rate indication.

7. The system of claim 6, wherein the optical receiver and the optical transmitter each include a synchronization unit, the synchronization units of the optical transmitter and the optical receiver to provide a communication link between the optical transmitter and the optical receiver that is separate from optical signals transmitted by the optical transmitter and optical signals received by the optical receiver, the optical receiver to use the communication link provided by the synchronization units to provide the information related to the error rate indication to the optical transmitter.

8. The system of claim 6, wherein the optical receiver is part of an optical transceiver.

9. The system of claim 8, wherein the optical transceiver to further provide the information related to the error rate indication to the optical transmitter via an optical signal sent to another optical transceiver that includes the optical transmitter.

10. The system of claim 9, wherein the optical signal sent by the optical transceiver includes tone modulation to provide the error rate indication to the optical transmitter.

11. The system of claim 1, wherein the predetermined set of error correction codes includes a selection of no error correction encoding.

12. The system of claim 2, wherein the error rate indicator is implemented using the error correction decoder.

13. An optical communication system, comprising:
an optical transmitter, wherein the optical transmitter includes error correction encoder means for encoding data according to an error correction code selected from a predetermined set of error correction codes having differing data transfer rates; and
an optical receiver operatively coupled to the optical transmitter, wherein the optical receiver includes error correction decoder means for decoding data according to the error correction code selected in the error correction encoder.

14. The system of claim 13, wherein the optical receiver further includes an error rate indicator, wherein the error rate indicator to provide an indication of an error rate of an optical signal received by the optical receiver.

15. The system of claim 14, wherein the error rate indicator is coupled to an optical detector/amplifier of the optical receiver.

16. The system of claim 14, wherein the error rate indicator to provide an indication of a power level of the optical signal received by the optical receiver.

17. The system of claim 14, wherein the optical receiver to further provide information related to the error rate indication from the error rate indicator to the optical transmitter.

18. The system of claim 17, wherein the error correction encoder means selects an error correction code of the predetermined set of error correction codes in dependence on the information related to the error rate indication.

19. The system of claim 18, wherein the optical receiver and the optical transmitter each include synchronization means for providing a communication link between the optical transmitter and the optical receiver that is separate from optical signals transmitted by the optical transmitter and optical signals received by the optical receiver, the optical receiver to use the synchronization means to provide the information related to the error rate indication to the optical transmitter.

20. The system of claim 18, wherein the optical receiver is part of an optical transceiver.

21. The system of claim 20, wherein the optical transceiver to further provide the information related to the error rate indication to the optical transmitter via an optical signal sent to another optical transceiver that includes the optical transmitter.

22. The system of claim 21, wherein the optical signal sent by the optical transceiver uses tone modulation to provide the error rate indication to the optical transmitter.

23. The system of claim 13, wherein the predetermined set of error correction codes includes a selection of no error correction encoding.

24. The system of claim 14, wherein the error rate indicator is implemented using the error correction decoder.

25. An optical transceiver for use in a communication system, the optical transceiver comprising:
an error correction encoder, wherein the error correction encoder to output data that is encoded according to an error correction code selected from a predetermined set of error correction codes having differing data transfer rates, the predetermined set also including a selection of no error correction encoding;
a laser/driver unit coupled to the error correction encoder, wherein the laser/driver unit to transmit optical signals modulated with data from the error correction encoder;
an optical detector/amplifier to receive optical signals; and
an error correction decoder coupled to the optical detector/amplifier, wherein the error correction decoder to decode data according to an error correction code selected from the predetermined set of error correction codes.

26. The optical transceiver of claim 25, further comprising an error rate indicator, wherein the error rate indicator to provide an indication of an error rate of an optical signal received by the optical transceiver.

27. The optical transceiver of claim 26, wherein the error rate indicator is coupled to the optical detector/amplifier.

28. The optical transceiver of claim 26, wherein the error rate indicator to provide an indication of a power level of the optical signal received by the optical transceiver.

29. The optical transceiver of claim 26, wherein information related to the error rate indication from the error rate indicator is provided to the error correction encoder.

30. The optical transceiver of claim 29, wherein the error correction encoder to further select an error correction code of the predetermined set of error correction codes in dependence on the information related to the error rate indication.

31. The optical transceiver of claim 29, wherein the optical transceiver to further provide the information related to the error rate indication to another optical transceiver via an optical signal sent to the other optical transceiver, the other optical transceiver being the source of the received optical signal.

32. The optical transceiver of claim 31, wherein the optical signal sent by the optical transceiver to the other optical transceiver includes tone modulation to provide the error rate indication to the optical transmitter.

33. The optical transceiver of claim 25, wherein the error correction encoder comprises a field programmable gate array.

34. The optical transceiver of claim 33, wherein the field programmable gate array is dynamically reprogrammable to encode data according to an error correction code selected from the predetermined set of error correction codes.

35. A method for use in an optical communication system, the method comprising:
measuring a parameter of an optical signal received in the optical communication system, wherein the parameter is indicative of an error rate of data contained in received optical signals;
selecting an error correction code from a predetermined set of error correction codes based on the measurement; and
configuring the optical communication system to use the selected error correction code.

36. The method of claim 35 wherein the predetermined set of error correction codes includes a selection of no error correction coding.

37. The method of claim 35, wherein the parameter is a power level of received optical signals.

38. The method of claim 35 wherein configuring the optical communication system to use the selected error correction code comprises:
encoding data to be transmitted in an optical signal according to the selected error correction code;
providing to an intended receiver of the optical signal an indication of the selected error correction code; and
transmitting the encoded data.

39. The method of claim 35 wherein configuring the optical communication system to use the selected error correction code comprises providing information associated with the selected error correction code to a transmitter of the received optical signal.

40. An optical communication system, comprising:
means for measuring a parameter of an optical signal received in the optical communication system, wherein the parameter is indicative of an error rate of data contained in received optical signals;
means for selecting an error correction code from a predetermined set of error correction codes based on the measurement; and
means for configuring the optical communication system to use the selected error correction code.

41. The system of claim 40, wherein the predetermined set of error correction codes includes a selection of no error correction coding.

42. The system of claim 40, wherein the parameter is a power level of received optical signals.

43. The system of claim 40 wherein the means for configuring comprises:
means for encoding data to be transmitted in an optical signal according to the selected error correction code;
means for providing to an intended receiver of the optical signal an indication of the selected error correction code; and
means for transmitting the encoded data.

44. The system of claim 40 wherein the means for configuring comprises means for providing information associated with the selected error correction code to a transmitter of the received optical signal.
